(19) United States
(12) Patent Application Publication
(10) Pub. No.: US 2005/0009714 A1
(43) Pub. Date: Jan. 13, 2005

(54) Process and slurry for chemical mechanical polishing

(75) Inventors: Pao Cheng Chen, Lingya Chiu (TW); Tsung-Ho Lee, Ligang Shiang (TW); Wen Cheng Liu, Linyuan Shiang (TW); Yen Liang Chen, Dungshan Shiang (TW)

Correspondence Address: SCULLY SCOTT MURPHY & PRESSER, PC, 400 GARDEN CITY PLAZA, GARDEN CITY, NY, 11530, US

(73) Assignee: Eternal Chemical Co., Ltd., Kaohsiung (TW)

(21) Appl. No.: 10/844,730

(22) Filed: May 13, 2004

(30) Foreign Application Priority Data
May 13, 2003 (TW) 092112941

(51) Int. Cl. C10M 101/00; H01L 21/302; H01L 21/461

(52) U.S. Cl. 508/591

(57) ABSTRACT

The invention provides a chemical-mechanical polishing process for polishing the surface of a semiconductor wafer, which comprises the steps of separately preparing a chemical agent and an abrasive agent, combining them into an abrasive slurry at the beginning of the polishing procedure or at the platen end, and polishing the metal layer on the surface of the semiconductor wafer with said admixed abrasive slurry. The invention further provides a chemical-mechanical polishing slurry for polishing the surface of a semiconductor wafer, characterized by being prepared by the steps of separately preparing a chemical agent and an abrasive agent and then combining them at the beginning of the polishing procedure or at the platen end, wherein said chemical agent comprises an aqueous medium, a corrosion inhibitor, and an ionic surfactant, and said abrasive agent comprises abrasive particles and deionized water.

### FIELD OF THE INVENTION

The invention pertains to a chemical-mechanical polishing process which is useful in polishing the surface of semiconductor wafers.

### DESCRIPTION OF THE PRIOR ART

Chemical mechanical polishing (CMP) is a planarization technique developed for solving the problem associated with the difficulty in focus during a photolithography process for producing integrated circuits owing to the difference in the height of deposited films. Chemical-mechanical polishing technique was first applied to the production of the elements with a size in the order of 0.5 microns. With the reduction in the size of the elements, the chemical-mechanical polishing technique was applicable to an increased number of layers. Until the elements were developed to the order of 0.25 microns, the chemical-mechanical polishing became a main and essential planarization technique. In general, the polishing process for producing a wire circuit comprises mounting a semiconductor wafer on a spinning platen equipped with an abrasive head and applying an abrasive slurry comprising abrasive particles and an oxidant to the surface of the wafer to enhance the abrasion efficacy.

Conventional polishing processes use pre-formulated polishing slurries. A conventional process for preparing a polishing slurry comprises adding abrasive particles to water first and continuously mixing them with a mixer having high shearing force till the abrasive particles are completely suspended in water to form a slurry. Then, water is added to the slurry again so as to achieve the desired solids content of the abrasive particles in the slurry. Other additives are introduced into the resultant high purity slurry and then aqueous ammonia, for example, is added to the slurry to control the pH value of the slurry to be within a desired range.

However, when the commercially available slurry is stored for a period of time, the abrasive particles previously suspended therein are usually precipitated, which results in difficulty in the polishing. Therefore, the shelf life of the polishing slurry is generally not long.

Moreover, since the conventional polishing slurry is prepared by pre-mixing the components of the slurry, the proportion of each component of the slurry composition is constant. Nevertheless, it is inconvenient for more complicated chemical mechanical polishing processes, since different processes require different concentrations of abrasive particle solids. If the concentration of abrasive particle solids is adjusted to be suitable for a certain process, it will result in the complication of the process and increase the cost.

In the process for producing integrated circuits, Ta or TaN film is most commonly used to enhance the adhesion of copper to a silica insulation layer. Moreover, Ta or TaN film is also used as a barrier layer. In theory, Ta or TaN should be polished in a rate close to that of copper. Nevertheless, since Ta has a high chemical resistance and is hard to be oxided, effective polishing of Ta is usually difficult to achieve in the process for producing copper circuits. Furthermore, since it is hard to remove the barrier film by polishing, this normally causes dishings on copper circuits.

Additionally, in the copper processing, Cu film will be annealed, and a layer of dense copper oxide will be easily generated on the Cu film. Furthermore, because of the uniformity problem associated with the CMP process, when part of copper on the wafer is polished off and dishings are generated, undesired copper residue can still be found on the wafer. Therefore, there is a demand for a CMP process in which copper residue can be removed fast so as to reduce dishings on copper circuits and to increase production capacity.

Ta and TaN are the main materials for barrier layers utilized in current copper process. If the barrier layer is regarded as the stop layer in the Cu metal removing step, the selectivity of the abrasive agent to Cu metal and to the barrier layer will be very critical. Since the barrier metal film becomes thinner in an advanced process, the selectivity of the polishing slurry must be higher to facilitate the operation of the process.

Upon extensive researches, the inventors of the present invention found that a chemical-mechanical polishing slurry prepared by the steps of separately preparing a chemical agent and abrasive agent and combining the chemical agent and abrasive agent at the beginning of polishing procedure or at the platen end, can effectively enhance the selectivity of Cu metal to TaN and further prevent the generation of the dishings on copper circuits. Moreover, since the chemical agent and abrasive agent are respectively formulated, the precipitation of abrasive particles can be avoided. Furthermore, by the control of the mixing amounts of the chemical agent and abrasive agent, polishing slurries having different proportions of components can be obtained to be used in different polishing processes, and the above defects can be overcome more economically and effectively.

### SUMMARY OF THE INVENTION

One of the objects of the present invention is to provide a chemical-mechanical polishing process for polishing the surface of a semiconductor wafer, characterized by the steps of separately preparing a chemical agent and an abrasive agent; and combining them into an abrasive slurry at the beginning of the polishing procedure or at the platen end, and polishing the metal layer on the surface of the semiconductor wafer with said admixed abrasion slurry.

Another object of the present invention is to provide a chemical-mechanical polishing slurry for polishing the surface of a semiconductor wafer, wherein said slurry is prepared by the steps of separately preparing a chemical agent and an abrasive agent and then combining them at the beginning of the polishing procedure or at the platen end, wherein said chemical agent comprises 70 to 99.5% by weight of an aqueous medium, 0.01 to 1% by weight of a corrosion inhibitor, and 0.01 to 5% by weight of an ionic surfactant, and said abrasive agent comprises 0.1 to 20% by weight of abrasive particles and deionized water.

### DETAILED DESCRIPTION OF THE INVENTION

The present invention provides a chemical-mechanical polishing process for polishing the surface of a semiconductor wafer, characterized by the steps of separately preparing a chemical agent and an abrasive agent and combining them into an abrasive slurry at the beginning of the polishing procedure or at the platen end, and polishing the metal layer on the surface of the semiconductor wafer with said admixed abrasive slurry. Generally, the metal layer to be polished off is copper. Said chemical agent comprises an aqueous medium, a corrosion inhibitor, and an ionic surfactant. Said abrasive agent comprises abrasive particles and deionized water.

According to one embodiment of the present invention, said chemical agent and abrasive agent are combined into an abrasive slurry at the beginning of the polishing procedure, and said admixed slurry is then introduced onto the abrasive pad to conduct subsequent polishing procedures.

According to another embodiment of the present invention, said chemical agent and said abrasive agent are directly combined into an abrasive slurry at the platen end, wherein said chemical agent and said abrasive agent are introduced onto an abrasive pad through different tubes.

The present invention further provides a chemical-mechanical polishing slurry for polishing the surface of a semiconductor wafer, wherein said slurry is prepared by the steps of separately preparing a chemical agent and an abrasive agent and then combining them at the beginning of the polishing procedure or at the platen end, wherein said chemical agent comprises an aqueous medium, a corrosion inhibitor, and an ionic surfactant. For example, said chemical agent may comprise 70 to 99.5% by weight of an aqueous medium, 0.01 to 1% by weight of a corrosion inhibitor, and 0.01 to 5% by weight of an ionic surfactant. Said abrasive agent comprises abrasive particles and deionized water, wherein the abrasive particles are present in an amount ranging from 0.1 to 20% by weight, preferably from 0.5 to 5.0% by weight.

The aqueous medium used in this invention is well known to those skilled in the art. For example, water, preferably deionized water may be used in the preparation of the slurry.

The corrosion inhibitor used in the present invention is a triazole compound selected from the group consisting of benzotriazole, 1,3,5-triazine-2,4,6-triol, 1,2,3-triazole, 3-amino-1,2,4-triazole, 3-nitro-1,2,4-triazole, purpald®, benzotriazole-5-carboxylic acid, 3-amino-1,2,4-triazole-5-carboxlic acid, 1-hydroxy-benzotriazole and nitro-benzotriazole. Preferably, the corrosion inhibitor used in the present invention is benzotriazole.

The ionic surfactant used in the present invention may be, for example, an anionic surfactant.

There is no specific limitation on the abrasive particles used in the present invention, which may be any commercially available abrasive particles, such as Al₂O₃, CeO₂, and Fe₂O₃. These abrasive particles normally have a high purity and a high surface area. Preferably, the abrasive particles used in the present invention are Al₂O₃ particles.

The polishing slurry of the present invention may optionally comprise an oxidant in the range of 0.1 to 5% by weight. It is well known to persons skilled in the art to add additional oxidants to a polishing slurry. There is no specific limitation on the oxidant used in the present invention. Suitable examples of the oxidant include, but not limited to, H₂O₂, Fe(NO₃)₃, KIO₃, CH₃COOH and KMnO₄. Preferably, the oxidant used in the present invention is H₂O₂.

The polishing slurry of the present invention may further comprise other ingredients that are conventionally used chemical-mechanical abrasive compositions and result in no adverse effect on the polishing slurry of the present invention. For example, the polishing slurry of the present invention may comprise an organic acid for enhancing the chelating rate, or a base or acid for adjusting the pH value, such as aqueous ammonia or nitric acid. Appropriate organic acids include, but not limited to, formic acid, acetic acid, propionic acid, butyric acid, valeric acid, hexanoic acid, malonic acid, glutaric acid, adipic acid, oxalic acid, citric acid, malic acid or tartaric acid.

The present invention will be further described by, but not limited to, the following examples. Any modifications or changes with reference to the present invention that can be easily accomplished by persons skilled in the art will be covered in the domain of the present invention.

### EXAMPLES

### Polishing Test

A. Instrument: AMAT/Mirra
B. Conditions:
   Membrane Pressure: 2 psi
   Inner Tube: Vent
   Retaining Ring: 2.6 psi
   Platen Speed: 93 rpm
   Carrier Speed: 87 rpm
   Temperature: 25° C.
   Pad Type: IC1000, k-x y.
   Slurry Velocity: 150 ml/min.
C. Wafer: Patterned wafer^{□}commercially available from Sematech, Type: 0.25 μm line width 854CMP017 wafer.
D. Slurry: The abrasive slurries illustrated in the examples, each of which further contains 3.0 wt % H₂O₂.

### Procedure of Polishing Test

The invention used Mirra polishing machine of Applied Materials for polishing. The signal obtained from End Point System was configured as EP2 signal for the polishing procedure. During polishing, 20% over-polishing was conducted after the polishing with each of the abrasive slurries shown in the examples reached EP2. The wafers were cleaned by Evergreen Model 10X Cleaner of Solid State Equipment Corporation after being polished and then dried with N₂. KLA-Tencor P-11 Surface Profiler was then used to measure the level of the copper dishing. Copper wire with a width of 100 μm was used as the measuring reference point and its dishing relative to that of the barrier layer was measured.

### Example 1

Colloidal silica was used as abrasive particles.

The slurry, including the chemical agent and abrasive agent, has the following composition:
Colloidal silica: 3.0 wt %;
Benzotriazole (BTA): 0.1 wt %^{□}
Adipic acid: 0.2 wt %^{□}
Surfynol CT-161 (an anionic surfactant produced by Air Products Corps.): 0.1 wt %^{□}
Balance: aqueous ammonia or nitric acid for adjusting the pH value, and deionized water.

The chemical agent and abrasive agent are introduced onto the abrasive pad through separate tubes. Results of the polishing test are shown in Table 1.

### Example 2

A slurry having a composition similar to Example 1 was prepared in the same way, except that the abrasive particles were changed to alumina particles. Results of the polishing test are shown in Table 1.

### Example 3

A slurry having a composition similar to Example 2 was prepared in the same way, except that the pH value was changed to be in the range of from 5 to 6. Results of the polishing test are shown in Table 1.

### Example 4

A slurry having a composition similar to Example 2 was prepared in the same way, except that the concentration of the alumina was changed to 1 wt %. Results of the polishing test are shown in Table 1.

### Example 5

A slurry having a composition similar to Example 2 was prepared, except that the chemical agent and abrasive agent were pre-mixed to form the slurry and then introduced onto the pad. Results of the polishing test are shown in Table 1.

### Example 6

A slurry having a composition similar to Example 2 was prepared in the same way, except that Surfynol 440 (a non-ionic surfactant produced by Air Products Corps.) was used instead of Surfynol CT-161. Results of the polishing test are shown in Table 1.

### Example 7

A slurry having a composition similar to Example 2 was prepared in the same way, except that the concentration of adipic acid was increased from 0.2 wt % to 0.5 wt %. Results of the polishing test are shown in Table 1.

### Example 8

A slurry having a composition similar to Example 7 was prepared in the same way, except that formic acid was used instead of adipic acid. Results of the polishing test are shown in Table 1.

### Example 9

A slurry having a composition similar to Example 2 was prepared in the same way, except that the concentration of Surfynol CT-161 was increased from 0.1 wt % to 0.2 wt %. Results of the polishing test are shown in Table 1.

### Example 10

A slurry having a composition similar to Example 1 was prepared in the same way, except that Surfynol 440 (a non-ionic surfactant produced by Air Products Corps.) was used instead of Surfynol CT-161. Results of the polishing test are shown in Table 1.

TABLE 1

| | | | | | | | Dishing |
|---|---|---|---|---|---|---|---|
| | | | | | Cu | TaN | (Å/100 μm |
| | | Solids | | | removal | removal | Cu |
| | Abrasive particles | content | Chemical added and | | rate | rate | line |
| Ex. | or mixing order | (%) | amount thereof (wt. %) | pH | (Å/min) | (Å/min) | width) |
| 1 | Colloidal silica | 3 | Benzotriazole (0.1%) | 3-4 | 4985 | 168 | 1862 |
| | | | Adipic acid (0.2%) | | | | |
| | | | Surfynol CT-161 (0.1%) | | | | |
| | | | H₂O₂ (3.0%) | | | | |
| 2 | Alumina | 3 | Benzotriazole (0.1%) | 3-4 | 8526 | 15 | 220 |
| | | | Adipic acid (0.2%) | | | | |
| | | | Surfynol CT-161 (0.1%) | | | | |
| | | | H₂O₂ (3.0%) | | | | |
| 3 | Alumina | 3 | Benzotriazole (0.1%) | 5-6 | 7848 | 20 | 249 |
| | | | Adipic acid (0.2%) | | | | |
| | | | Surfynol CT-161 (0.1%) | | | | |
| | | | H₂O₂ (3.0%) | | | | |
| 4 | Alumina | 1 | Benzotriazole (0.1%) | 3-4 | 7906 | 14 | 198 |
| | | | Adipic acid (0.2%) | | | | |
| | | | Surfynol CT-161 (0.1%) | | | | |
| | | | H₂O₂ (3.0%) | | | | |
| 5 | Alumina pre- | 3 | Benzotriazole (0.1%) | 3-4 | 9363 | 12 | 380 |
| | mixed with the | | Adipic acid (0.2%) | | | | |
| | chemical agent | | Surfynol CT-161 (0.1%) | | | | |
| | | | H₂O₂ (3.0%) | | | | |
| 6 | Alumina | 3 | Benzotriazole (0.1%) | 3-4 | 8263 | 19 | 1548 |
| | | | Adipic acid (0.2%) | | | | |
| | | | Surfynol 440 (0.1%) | | | | |
| | | | H₂O₂ (3.0%) | | | | |
| 7 | Alumina | 3 | Benzotriazole (0.1%) | 3-4 | 7648 | 16 | 257 |
| | | | Adipic acid (0.5%) | | | | |
| | | | Surfynol CT-161 (0.1%) | | | | |
| | | | H₂O₂ (3.0%) | | | | |
| 8 | Alumina | 3 | Benzotriazole (0.1%) | 3-4 | 8430 | 16 | 262 |
| | | | Formic acid (0.5%) | | | | |
| | | | Surfynol CT-161 (0.1%) | | | | |
| | | | H₂O₂ (3.0%) | | | | |
| 9 | Alumina | 3 | Benzotriazole (0.1%) | 3-4 | 7820 | 12 | 192 |
| | | | Adipic acid (0.2%) | | | | |
| | | | Surfynol CT-161 (0.2%) | | | | |
| | | | H₂O₂ (3.0%) | | | | |
| 10 | Colloidal silica | 3 | Benzotriazole (0.1%) | 3-4 | 4864 | 182 | 2568 |
| | | | Adipic acid (0.2%) | | | | |
| | | | Surfynol 440 (0.1%) | | | | |
| | | | H₂O₂ (3.0%) | | | | |

The results of Examples 1 and 2 show that changing the abrasive particles to alumina achieves better abrasive selectivity ratio and performs better in preventing copper dishing.

The results of Examples 2 and 3 show that adding alumina to the slurries of different pH values can enhance abrasive selectivity ratio of both these slurries and prevent copper dishing.

The results of Examples 2 and 4 show that adding alumina at different concentrations to the slurries can increase abrasive selectivity ratio and prevent copper dishing.

The results of Examples 2 and 5 show that mixing the components of the slurry at the platen end can further prevent copper dishing.

The results of Examples 1 and 10 and Examples 2 and 6 show that adding an ionic surfactant to the slurries can increase abrasive selectivity ratio and prevent copper dishing.

The results of Examples 2 and 7 show that the addition of adipic acid to the slurries in the polishing process at different concentrations does not affect selectivity ratio and copper dishing.

The results of Examples 7 and 8 show that the addition of different organic acids to the slurries in the polishing process does not affect selectivity ratio and copper dishing.

The results of Examples 2 and 9 show that adding an ionic surfactant at different concentrations to the abrasive slurries can increase selectivity ratio and prevent copper dishing.

1. A chemical-mechanical polishing process for polishing the surface of a semiconductor wafer, characterized by the steps of separately preparing a chemical agent and an abrasive agent, and combining them into an abrasive slurry at the beginning of the polishing procedure or at the platen end, and polishing the metal layer on the surface of the semiconductor wafer with said admixed abrasion slurry, wherein said chemical agent comprises an aqueous medium, a corrosion inhibitor, and an ionic surfactant, and said abrasive agent comprises abrasive particles and deionized water.

2. The process according to claim 1, wherein said chemical agent and said abrasive agent are introduced onto the abrasive pad of the platen through separate tubes, and then combined into said abrasive slurry.

3. The process according to claim 1, wherein said chemical agent comprises 70 to 99.5% by weight of the aqueous medium, 0.01 to 1% by weight of the corrosion inhibitor, and 0.01 to 5% by weight of the ionic surfactant.

4. The process according to claim 1, wherein said aqueous medium is deionized water, said corrosion inhibitor is benzotriazole, and said ionic surfactant is an anionic surfactant.

5. The process according to claim 1, wherein said abrasive agent comprises 0.1 to 20% by weight of alumina, and deionized water.

6. The process according to claim 1, wherein said metal layers are copper layers.

7. A chemical-mechanical polishing slurry for polishing the surface of a semiconductor wafer, characterized by being prepared by the steps of separately preparing a chemical agent and an abrasive agent and then combining them at the beginning of a polishing procedure or at the platen end, wherein said chemical agent comprises an aqueous medium, a corrosion inhibitor, and an ionic surfactant, and said abrasive agent comprises abrasive particles and deionized water.

8. The polishing slurry according to claim 7, wherein said chemical agent comprises 70 to 99.5% by weight of the aqueous medium, 0.01 to 1% by weight of the corrosion inhibitor, and 0.01 to 5% by weight of the ionic surfactant.

9. The polishing slurry according to claim 8, wherein said aqueous medium is deionized water, said corrosion inhibitor is benzotriazole, and said ionic surfactant is an anionic surfactant.

10. The polishing slurry according to claim 7, wherein said abrasive agent comprises 0.1 to 20% by weight of alumina, and deionized water.
